(19) United States
(12) Patent Application Publication
(10) Pub. No.: US 2011/0073843 A1
(43) Pub. Date: Mar. 31, 2011

(54) Organic Light Emitting Display and Process for its Manufacturing

(75) Inventor: Antonio Bonucci, Milano Mi (IT)

(73) Assignee: SAES GETTERS S.P.A., Lainate MI (IT)

(21) Appl. No.: 12/441,291

(22) PCT Filed: Sep. 20, 2007
(86) PCT No.: PCT/EP2007/060005

§ 371 Date: Nov. 6, 2009

(30) Foreign Application Priority Data
Sep. 29, 2006 (IT) MI2006A 001872

(51) Int. Cl. H01L 51/52; H01L 51/56

(52) U.S. Cl. 257/40; 438/46; 257/E51.018

(57) ABSTRACT

An organic electro-luminescent display is provided, including a thin layer (16) of an electron-donor metal between cathodes (17) and an organic electron transport layer (15), and a partial doping of the latter layer with the same metal.

### CROSS-REFERENCE TO RELATED APPLICATIONS

This application is a Section 371/Continuation of International Application No. PCT/EP2007/060005, filed Sep. 20, 2007, which was published in the English language on Apr. 3, 2008, under International Publication No. WO 2008/037654 A1 and the disclosure of which is incorporated herein by reference.

### BACKGROUND OF THE INVENTION

The present invention relates to an organic light emitting display and to a process for its manufacture.

The organic light emitting displays are known in the field as OLEDs. The definition also relates to light emitting diodes, which are the units forming the displays, but it is more commonly used with reference to the displays.

In short, an OLED is comprised of a first transparent planar support (made of glass or plastic); a second support, not necessarily transparent, that may be made of glass, metal or plastic, which is essentially planar and parallel to the first support and is fixed along the periphery of the latter in order to form a closed space; and an active structure for the formation of an image in the closed space. The active structure is generally formed on the first transparent support by depositing in sequence:

a first series of linear transparent electrodes parallel to each other directly deposited on the first support (and generally made of a mixed oxide of indium and tin, known in the field with the abbreviation ITO), generally having anode functionality;

a layer of an organic material, conductor of electronic holes, briefly indicated in the field as HTL (Hole Transport Layer), in contact with the electrodes of the first series;

a layer of a organic luminescent material (EML, emitting layer) on the HTL layer;

a layer of an organic electron conductor material, referred to in the field as an ETL (Electron Transport Layer), on the EML layer; and

a second series of linear electrodes parallel to each other, having a perpendicular orientation with respect to those of the first series and provided with cathode functionality, deposited onto the ETL layer.

For a more detailed description of the structure and operation of OLED displays reference may be made, for example, to U.S. Pat. Nos. 6,013,384; 6,284,393; and 6,509,109 and to Japanese Patent Application No. JP-A-09-078058.

It is known that the addition of small amounts of electron-donor metals, particularly alkaline metals, to the structure of an OLED improves properties like power consumption, turning-on voltage and brightness.

Until now researchers have focused on two ways for inserting these metals into OLEDs.

According to the first mode, the metals are inserted in the form of very thin layers, on the order of few nanometers, between the cathodes and the ETL organic layer. It has been observed that this method reduces the turning-on voltage of the OLED (called “built-in voltage” in the field) and consequently its power consumption. This approach is disclosed, for instance, in U.S. Pat. No. 6,255,774.

According to the second mode, the metal is used as a doping element of the organic electron transport layer (or at least of its portion closer to the cathodes). OLED devices manufactured according to this mode exhibit a lower resistance to the current flow and thus a lower consumption or a sensibly higher brightness with respect to non-doped devices. The intensity of these effects increases with an increase in the doping amount up to a molar ratio between the metal and the organic molecules of the layer of 1 to 1, after which higher doping levels do not lead to further advantages. This second approach is disclosed, for instance, in U.S. Pat. No. 6,013,384 and in the article “Bright organic electroluminescent devices having a metal-doped electron-injecting layer”, by J. Kido and T. Matsumoto (Applied Physics Letters, vol. 73, No. 20; pp. 2866-2868 (November 1998)).

In practice, the two above-illustrated situations tend to become modified over time due to the diffusion of the employed metals inside the ETL layer. In the first case, the metal diffuses into the ETL, reducing the initial thickness of the metal layer interposed between cathodes and ETL, until possibly reducing to zero the advantage of the presence of the metal layer and giving rise to a non-homogeneous doping of the ETL. In the second case, the metal also diffuses toward the ETL-cathodes interface, thus evolving towards a situation analogous to that of the first case. However, these phenomena are uncontrolled, whereby the electrical properties of the OLED are not reproducible and evolve in an uncontrolled manner during the life of the display.

### BRIEF SUMMARY OF THE INVENTION

An object of the present invention is to provide an OLED display and a process for its manufacture that achieves and preserves the best functional properties of the display itself.

These and other objects are achieved by means of the present invention, which in a first aspect thereof relates to an OLED display characterized by comprising a thin layer of electron-donor metal between the cathodes and an ETL layer, and an ETL layer doped in the portion adjacent to the thin metal layer.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic sectional view of an OLED display according to an embodiment of the invention; and

FIGS. 2a-2d are schematics showing the main manufacturing steps of an OLED display according to an embodiment of the method of the invention.

### DETAILED DESCRIPTION OF THE INVENTION

OLED displays are made up of a plurality of diodes: for convenience, the rest of the description will refer to the production of a single diode.

In the drawings, the proportions among the various parts have not been respected in order to point out the details of greater interest.

The inventors have found that in an OLED display manufactured according to the invention, the diffusion phenomena of the electron-donor metal are reduced with respect to what occurs in known displays. Although the phenomenon has not yet been studied in depth, it is believed that the presence of an already doped ETL reduces the diffusion of the metal layer in contact with the cathodes, and consequently maintains its functionality for a longer time. Similarly, it is believed that the presence of the metal layer reduces the diffusion of the metal from the ETL toward the interface with the cathodes. The consequence is a lower shift over time of the electric characteristics of the OLEDs of the invention.

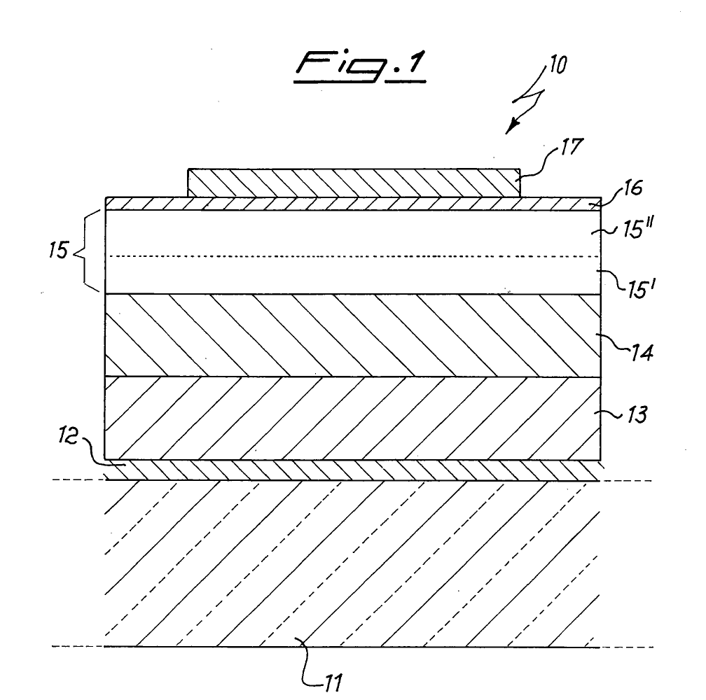

FIG. 1 shows an OLED diode 10 used to form the display of the invention. The diode is made up of a sequence of superimposed layers deposited onto a transparent support 11, generally made of glass. On this support anodes 12 are deposited (the drawing shows only one anode), being transparent in turn, generally made of ITO and manufactured by screen-printing or by cathode deposition with a suitable masking. On the anodes, an organic HTL layer 13 is present, generally manufactured with nitrogenated aromatic compounds (aryl amines, derivatives of pyridines or pyrazines, etc.). The EML layer 14 of organic material is then provided, wherein the luminescence is generated upon recombination of electrons and holes transported by ETL and HTL layers, respectively. This layer may be manufactured, for example, from tris(8-hydroxyquinoline)aluminum (often indicated in the field with the abbreviation Alq). On layer 14 the electron transport layer ETL 15 is provided and the electron-donor metal layer 16 is present over ETL layer 15. Finally, on the external surface of layer 16, the cathode 17 is provided, generally made of aluminum, to which the electrical contact (not shown) for the supply of diode 10 is connected. Typical thicknesses for the different layers are: about 150 nanometers (nm) for anodes 12; about 120 nm for HTL layer 13; between 5 and 10 nm for EML layer 14; between 30 and 80 nm for ETL layer 15; between 0.2 and 5 nm for electron-donor metal layer 16, and between 200 and 300 nm for cathodes 17.

The characteristic elements of the diode of the invention are layers 15 and 16.

Layer 15 may be manufactured with the same Alq material of the EML layer and is formed of a portion 15′ directly contacting the EML layer and of a portion 15″. The portion 15′ is not intentionally doped with the electron-donor metal, although this may partially diffuse into portion 15′ during the life of the display. For the operation of the display, it is necessary to avoid having the electron-donor metal come into contact with and penetrate layer 14. Thus, the height of portion 15′ must be sufficient to ensure that the electron-donor metal is unable to pass through this entire height during the life of the device. This minimum height may be extrapolated from known data or from accelerated diffusion tests of the specific metal into the specific organic material. For instance, in the case in which layer 15 is made of Alq and the metal is lithium, it has been observed that a thickness of about 40 nm for portion 15′ ensures the required properties. On the contrary, portion 15″ is intentionally doped with the electron-donor metal during the manufacture of diode 10. The molar ratio between the doping metal and the organic molecules in portion 15″ is preferably between 1:100 and 2:1 and more preferably between 1:6 and 1:1.

The layer 16 of electron-donor metal is preferably made of lithium or cesium.

The metal used for doping portion 15″ and the one used to form layer 16 are not necessarily the same. For example, it is possible to use cesium for doping layer 15″ and lithium for forming layer 16.

In a second aspect thereof, the invention relates to a process for manufacturing diodes of type 10 and an OLED display comprised of a plurality of such diodes.

As it is known, anodes 12 are generally formed on the transparent support 11 via screen-printing techniques starting from hydroalcoholic suspensions of particles of a mixed oxide of indium and tin having submicronic size.

All the other layers are generally produced via evaporation, commonly by positioning the support (on which the anodes are already present) in an upside-down position in the upper portion of an evacuated thermostated chamber, wherein the sources of the various components of the OLED are provided. The evaporation of the various components from these sources may be controlled by mechanical elements (known in the field as “shutters”) opening or closing the specific source, by the control of the temperature, or by both these means at the same time. By means of calibration tests it is possible to determine the deposition rates of the various layers and thereby control their thickness by the evaporation time. Alternatively, it is possible to resort to gauges of the thickness of the material deposited, typically quartz microbalances (known as “quartz crystal monitor”, QCM) arranged in the chamber in proximity to support 11.

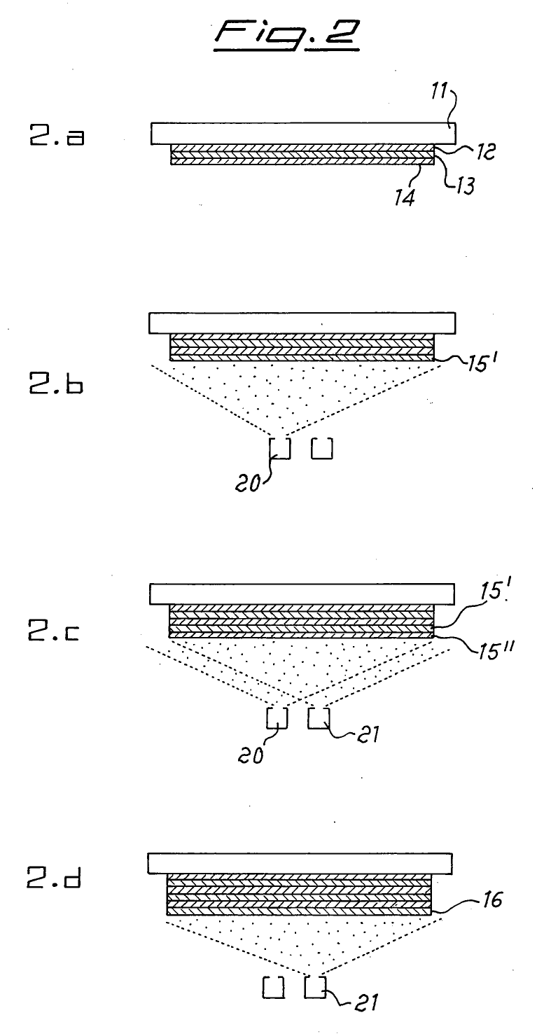

FIG. 2 shows the essential steps of the process of the invention, i.e. the formation of layers 15 and 16. For ease of representation, the evacuation chamber is not shown in the drawing, whereas the evaporation sources used for producing the characterizing components of the invention are shown. In this case, the details of the drawing are not to scale.

FIG. 2a shows a support 11 on which anodes 12, the HTL layer 13, and the EML layer 14 have already been formed in a known way.

FIG. 2b schematizes the manufacturing operation of portion 15′, which is obtained by evaporation of the organic material of the ETL layer (Alq, for instance) from source 20, for example a heated crucible. During this step, every other evaporation source provided inside the chamber is inactive.

In FIG. 2c, the manufacturing step of portion 15″ is shown. In this step, both source 20 of the organic material of the ETL and source 21 of the electron-donor metal are active. The simultaneous evaporation of the two materials occurs, thus depositing a homogeneous mixture of both of them. The source of the electron-donor metal may in turn be a simple crucible, possibly closed by a cover with an orifice, or an evaporator of a more complex shape, such as those shown in U.S. Pat. No. 6,753,648 and in International Patent Application No. WO 2006/057021, both in the Applicant's name. The achievement of the desired ratio between the organic component and the metal is accomplished through the control of the ratio of the evaporation rates of the two components, which may be controlled through the (different) temperatures at which sources 20 and 21 are kept and possibly through the size of apertures provided in covers arranged on the sources.

Finally, FIG. 2d shows the manufacture of layer 16. In this step, the source 20 of the organic material is made inactive (by interrupting its heating or by means of a shutter), while the evaporation of the metal of source 21 is continued for the time needed to obtain the desired thickness of layer 16. In FIGS. 2b-2d, the dashed zones between sources 20 and 21 and the layers under formation represent the “cones” of the vapors of the various materials.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1-6. (canceled)

7. An OLED display, comprising cathodes (17), an electron transport layer (15), and a thin layer (16) of an electron-donor metal between the cathodes (17) and the electron transport layer (15), wherein a portion (15″) of the electron transport layer (15) adjacent to the thin metal layer (16) is doped with an electron-donor metal, and wherein a thickness of the thin metal layer (16) is 0.2 to 5 nm.

8. The OLED display according to claim 7, wherein the electron-donor metal in the thin metal layer (16) and the electron-donor metal in the doped portion (15″) are the same metal.

9. The OLED display according to claim 7, wherein the electron transport layer (15) comprises a non-doped portion (15′), the electron-donor metal in the doped portion (15″) is lithium, and the non-doped portion (15′) of the electron transport layer (15) has a thickness of at least about 40 nanometers.

10. The OLED display according to claim 7, wherein the doped portion (15″) of the electron transport layer (15) comprises the electron-donor metal and organic molecules, and wherein a molar ratio between the electron-donor metal of the electron transport layer and the organic molecules is 1:100 to 2:1.

11. The OLED display according to claim 10, wherein the molar ratio is 1:6 to 1:1.

12. A process for manufacture of an OLED display, comprising the following steps:
arranging a transparent support (11) comprising transparent anodes (12) in an evacuation chamber provided with suitable sources for evaporation of organic and metal components;
depositing in sequence on the transparent anodes (12) a hole transport layer (13) comprising an organic material and an organic luminescent layer (14);
activating an evaporation source (20) comprising an organic material suitable for forming an organic electron transport layer (15), while keeping other sources provided in the chamber inactive, thus forming a non-doped portion (15′) of an electron transport layer (15);
activating an evaporation source (21) comprising an electron-donor metal, while keeping the source (20) active, thus forming a doped portion (15′) of the electron transport layer (15);
making the source (20) inactive, while keeping the evaporation source (21) active, thus forming an exclusively metal layer (16) on the electron transport layer; and
forming cathodes (17) on the metal layer (16) to yield the OLED display.
